(19) United States
(12) Patent Application Publication
(10) Pub. No.: US 2024/0232475 A1
(43) Pub. Date: Jul. 11, 2024

(54) MODELING METHOD FOR RAIL VEHICLE COLLISION FINITE ELEMENT DUMMY AND SIMULATION SYSTEM

(71) Applicant: Southwest Jiaotong University, Chengdu City (CN)

(72) Inventors: Lin JING, Chengdu City (CN); Zhenhao YU, Chengdu City (CN); Shaodong ZHENG, Chengdu City (CN); Kai LIU, Chengdu City (CN); Kaiyun WANG, Chengdu City (CN)

(21) Appl. No.: 18/350,120

(22) Filed: Jul. 11, 2023

(30) Foreign Application Priority Data
Jan. 10, 2023 (CN) 202310031397.X

(51) Int. Cl. G06F 30/23

(52) U.S. Cl. CPC G06F 30/23

(57) ABSTRACT

The present disclosure discloses a modeling method for a rail vehicle collision finite element dummy and simulation system, and relates to the technical field of rail transit. The method according to the present disclosure includes the following steps: S1: establishing a dummy finite element model with a characteristic parameter of a target human body; S2: establishing a multi-marshaling train collision finite element model considering a vehicle body collision energy-absorbing structure and wheel-rail rolling contact behavior; S3: establishing a rigid-flexible coupling model inside a rail vehicle; and S4: establishing a passive safety simulation and analysis system integrating the rail vehicle and the dummy finite element model.

### CROSS REFERENCE TO RELATED APPLICATION

This patent application claims priority of Chinese Patent Application No. 202310031397.X, filed with the China National Intellectual Property Administration on Jan. 10, 2023, the disclosure of which is incorporated by reference herein in its entirety as part of the present application.

### TECHNICAL FIELD

The present disclosure relates to the technical field of rail transit, and in particular, to a modeling method for a rail vehicle collision finite element dummy and simulation system.

### BACKGROUND

With the continuous progress of the construction of high-speed railways with a speed of 400 kilometers per hour, there is an urgent demand for train speed-up and high speed, which puts forward higher requirements for driving safety and reliability. The train collision safety and impact protection problem has attracted more and more attention. Although active safety measures of a system are taken for rail vehicles currently, it is still difficult to avoid train collision accidents caused by some human errors and unknown factors. In addition, once an accident happens, serious casualties and economic losses may be caused. With the continuous increase of the train running speed, huge collision energy may further increase catastrophic losses caused by a train collision. Since the core of passive safety of the train collision is to protect life safety of drivers and passengers, there is an urgent need to establish a rail vehicle and collision dummy integrated simulation and analysis system, and vigorously develop related research on the rail vehicle and collision dummy integrated simulation and analysis system.

In early research of rail vehicle collision simulation, a multi-body dynamics method was mainly used, and rigid bodies were used to simulate a bogie, a vehicle body, in-vehicle seats, a dummy model, etc. The interaction between rigid bodies was defined by different contact models, and an acting force was calculated according to penetration amount and contact characteristics. Since rail vehicles feature multi-marshaling, large mass, decentralized power, unrestraint to passengers, etc., a post-collision response attitude, dynamic instability behavior and derailment mechanism of the rail vehicles are very complicated. Therefore, in recent years, researchers have used an explicit finite element method to perform discretized modeling on a rail vehicle system to study impact deformation, dynamic response characteristics, energy dissipation, etc. of the vehicle body in a primary collision (collision between trains or between a train and an obstacle) of rail vehicles, and used a dummy finite element model to study an impact damage response of drivers and passengers in a secondary collision (collision between passengers and a device in the vehicle).

However, an existing rail vehicle collision safety simulation technology still has the following problems:
1. Currently, most dummy finite element models used for rail vehicle collision simulation are established based on characteristic sizes of European and American human bodies, but there are obvious differences in body characteristics between Chinese human bodies and European and American human bodies (such as a height, a weight, and a central position of each part of a human body). If the European and American dummy finite element models are directly used for driver and passenger damage evaluation and impact protection research during a rail vehicle collision, it is unfavorable for improving the passive safety protection capability of Chinese rail vehicles.
2. During modeling of existing rail vehicle collision simulation models, the impact of a primary collision on passenger damage is mostly ignored, only a finite element model of a single carriage is established, and a simplified load curve is applied to analyze a secondary collision damage response of drivers and passengers. This makes it impossible to directly establish a mapping relationship between a crashworthiness structure of a vehicle body and impact damage of drivers and passengers, and there are certain limitations in the guidance of a train crashworthiness design.
3. Existing rail vehicle collision finite element models mostly stick to existing standards and specifications, focusing on a longitudinal dynamic response and passive safety of a rail vehicle collision, and ignoring the coupling influence of a real wheel-rail rolling state and lateral and vertical effects on the damage response of drivers and passengers during the train collision, which cannot accurately reflect real damage of rail vehicle drivers and passengers.

Based on the above shortcomings, it is an urgent problem to be solved to establish an effective finite element model and simulation system to more accurately evaluate damage of drivers and passengers during a rail vehicle collision in China, so as to establish a mapping relationship between train impact protection performance and a biological damage response of passengers.

### SUMMARY

In view of the problems existing in the prior art, the present disclosure provides a modeling method for a rail vehicle collision finite element dummy and simulation system, which aims to provide a reference for impact damage evaluation of drivers and passengers of rail vehicles in China in a collision more accurately, and helps to establish an effective evaluation standard for impact-incurred biological damage of drivers and passengers in the field of rail transit in China, thereby further improving crashworthiness and operation safety of rail vehicles in China.

The present disclosure adopts the following technical solutions:

A modeling method for a rail vehicle collision finite element dummy and simulation system includes the following steps:
S1: establishing a dummy finite element model with a characteristic parameter of a target human body by calculating a scaling factor of the dummy finite element model in segments;
S2: establishing a multi-marshaling train collision finite element model considering a vehicle body collision energy-absorbing structure and wheel-rail rolling contact behavior;
S3: establishing a rigid-flexible coupling model inside a rail vehicle; and
S4: placing the dummy finite element model obtained in step S1 into the multi-marshaling train collision finite element model obtained in step S2, and establishing a passive safety simulation and analysis system integrating the rail vehicle and the dummy finite element model.

Preferably, a principle of calculating a scaling factor of the dummy finite element model in segments is as follows: body segment division is performed on a European and American dummy finite element model, local coordinate systems are established, deformable bodies are established on outer surfaces of different body segments, a human body model is completely enveloped in the deformable bodies, and the deformable bodies are used to control a shape of the model to realize scaling of the model.

Further, in step S1, the process of establishing a dummy finite element model with a characteristic parameter of a target human body by calculating a scaling factor of the dummy finite element model in segments includes:
first dividing a human body into a plurality of body segments, including a head, a neck, a trunk, an upper left arm, an upper right arm, a left forearm, a right forearm, a left thigh, a right thigh, a left shank, and a right shank, and then calculating a size scaling factor and a mass scaling factor for different body segments respectively, where λₓ, λ_{y} and λ_{z} are set as corresponding scaling factors of each body segment in X, Y and Z directions; in order to ensure that the scaled dummy finite element model and the dummy finite element model before the scaling have the same mass distribution, λₓ and λ_{y} are equal, and a relationship among λₓ, λ_{y} and λ_{z} is constrained by a mass scaling factor Rₘ;
the size scaling factor of the head is a ratio of sums of a head circumference, a head width and a head length, and is expressed as:

$${λ}_{x} = {λ}_{y} = {λ}_{z} = \frac{{( C + W + L )}_{S}}{{( C + W + L )}_{S}} , \qquad ( 1 )$$

where C represents the head circumference, W represents the head width, L represents the head length, and subscripts S and H represent the characteristic parameter of the target human body and a characteristic parameter of the European and American dummy finite element model respectively;
in order to ensure that the mass distribution of the scaled head is the same as that before the scaling, the mass scaling factor Rₘ is defined as the third power of the size scaling factor:

$$\frac{{M}_{S}}{{M}_{H}} = {R}_{m} = {λ}_{x}^{2} , \qquad ( 2 )$$

where the size scaling factor λ_{z} of the neck and trunk segments in the Z direction is determined by a vertical height of a human at a sitting posture, and is expressed as:

$${λ}_{z} = \frac{{( ESH )}_{S}}{{( ESH )}_{H}} , \qquad ( 3 )$$

where ESH is the vertical height at the sitting posture;
the mass scaling factor of the neck and trunk segments is determined according to a total weight of the human body, and is expressed as:

$${R}_{m} = \frac{{( TBW )}_{S}}{{( TBW )}_{H}} , \qquad ( 4 )$$

where TBW represents the weight of the human body;
in order to ensure that the mass distribution of the scaled dummy model is the same as that before the scaling, the size scaling factors λₓ and λ_{y} of the neck and trunk segments in the X and Y directions meet the following formula:

$${λ}_{x} = {λ}_{y} = \frac{\sqrt{{R}_{m}}}{\sqrt{{λ}_{z}}} , \qquad ( 5 )$$

and
a method for calculating the size scaling factors of the upper left arm, upper right arm, left forearm, right forearm, left thigh, right thigh, left shank and right shank segments is the same as a method for calculating the scaling factors of the neck and trunk segments, where the size scaling factor λ_{z} is a ratio of lengths of corresponding body segments of the target human body and the European and American dummy finite element model, and the mass scaling factor Rₘ is a ratio of mass of the corresponding body segments.

Further, when the dummy finite element model with the characteristic parameter of the target human is established by calculating the scaling factor of the dummy finite element model in segments, element mass of the scaled dummy finite element model is checked to ensure that the element mass of the scaled model meets requirements; a deviation from a target size and mass is determined by comparing size and mass parameters of each body segment of the scaled model with size and mass parameters of the corresponding body segment of the target human body, and if an absolute value of the deviation is greater than 10%, scaling is performed again; when absolute values of size and mass deviations of all body segments are within the range of 10%, the size and mass of the scaled dummy finite element model meet requirements, the element mass of the model is further checked, and unqualified mesh elements are modified or re-divided, so as to obtain the dummy finite element model meeting requirements for the characteristic parameter of the target human body.

Further, the European and American dummy finite element model includes, but is not limited to, THUMS, GHBMC and WSU models.

Preferably, in step S2, the process of establishing a multi-marshaling train collision finite element model considering a vehicle body collision energy-absorbing structure and wheel-rail rolling contact behavior includes:
establishing finite element models of the energy-absorbing structure, a vehicle body, a bogie and a track of a train, extracting a mid-plane of a train solid model according to geometric structural characteristics of the train, and performing discretization by using a four-node shell element, where components of a mid-plane model and components of the solid model have the same connection mode, and a device on the train is simulated by using a mass element, and is connected to the vehicle body by using a three-node beam element;
establishing a wheel-rail rolling contact finite element model according to a wheel tread type and a track structure, discretizing the rail and a wheelset by using an eight-node solid element, simulating materials of wheels and the rail by using an elastic-plastic material model considering a strain rate effect, and setting automatic surface-to-surface contact between the wheel and the rail to locally refine a mesh of a wheel-rail contact area; and
applying the same translation speed to both the wheelset and the vehicle body, and applying a corresponding rotation speed to the wheel, so as to obtain the multi-marshaling train collision finite element model considering the vehicle body collision energy-absorbing structure and the wheel-rail rolling contact behavior.

Further, in step S2, during the process of establishing a multi-marshaling train collision finite element model considering a vehicle body collision energy-absorbing structure and wheel-rail rolling contact behavior, according to mechanical properties of a coupler buffer apparatus, a discrete beam element is used to simulate the coupler buffer apparatus, and matches a material model, travel failure is imposed on the beam element, and when the travel of the coupler buffer apparatus is greater than rated travel, the beam element automatically fails; and
according to geometric structural characteristics of the bogie, a bogie frame, a traction apparatus, an axle box and a related structure are discretized by a four-node shell element; a discrete beam material model is used to simulate an air spring and an axle box spring, and a traction seat is connected to a vehicle body bolster in a connection mode of using a rigid body and a deformable body.

Further, a process of establishing a dynamic constitutive relation related to a strain rate of a vehicle body material includes:
studying dynamic mechanical properties of a vehicle body structural material in a wide strain rate range by using an MTS universal testing machine, a high-speed material testing machine and a separated Hopkinson bar apparatus, establishing the dynamic constitutive relation related to the strain rate of the vehicle body material, and introducing the dynamic constitutive relation into the vehicle body finite element model.

Preferably, in step S3, the process of establishing a rigid-flexible coupling model inside a rail vehicle includes:
during finite element modeling, simplifying a seat model, deleting parts irrelevant to seat motions and mechanical properties, and stiffening components that do not interact with drivers and passengers during a collision; discretizing a seat frame by using an eight-node solid element, and simulating a frame material; discretizing a backrest and a cushion of the seat by using an eight-node solid element, and simulating materials of the backrest and the cushion; discretizing a seat base by using an eight-node solid element, and simulating a base material; and connecting the seat finite element model to a train finite element model to obtain the rigid-flexible coupling model inside the rail vehicle.

Preferably, in step S4, the process of establishing a passive safety simulation and analysis system integrating the rail vehicle and the dummy finite element model includes:
placing the dummy finite element model with the characteristic parameter of the target human body that is obtained in step S1 and the rigid-flexible coupling model inside the rail vehicle that is obtained in step S3 into the multi-marshaling train collision finite element model considering the vehicle body collision energy-absorbing structure and the wheel-rail rolling contact behavior and obtained in step S2, and performing contact static analysis on a dummy-seat model by using a dynamic relaxation function of LS-DYNA, to obtain a static displacement field/stress field; inputting the obtained static displacement field/stress field into the finite element model for stress initialization, and establishing the passive safety simulation and analysis system integrating the rail vehicle and the dummy finite element model that predicts damage of target drivers and passengers.

The method according to the present disclosure can provide a reference for impact damage evaluation of drivers and passengers of rail vehicles in China in a collision more accurately, and help to establish an effective evaluation standard for impact-incurred biological damage of drivers and passengers in the field of rail transit in China, thereby further improving crashworthiness and operation safety of rail vehicles in China, and being of great significance to the sustainable and healthy development of rail transit in China.

### BRIEF DESCRIPTION OF THE DRAWINGS

The present disclosure will be described with reference to examples and accompanying drawings, in which:

FIG. 1 is a systematic flow chart of a modeling method according to the present disclosure;

FIG. 2 is a schematic diagram of segmentation of body segments of a human body and local reference coordinate systems according to an embodiment of the present disclosure;

FIG. 3 is a schematic diagram of a dummy finite element model of Chinese 50th percentile males according to Embodiment 2 of the present disclosure; and

FIG. 4 is a schematic diagram of a passive safety simulation and analysis system integrating a train and a dummy finite element model that is used to predict damage of Chinese drivers and passengers according to an embodiment of the present disclosure.

### DETAILED DESCRIPTION OF THE EMBODIMENTS

In order to make the objectives, technical solutions and advantages of the embodiments of the present application clearer, the following clearly and completely describes the technical solutions in the embodiments of the present application with reference to the accompanying drawings in the embodiments of the present application. Apparently, the described embodiments are some rather than all of the embodiments of the present application. The components of the embodiments of the present application, which are generally described and illustrated in the accompanying drawings herein, may be arranged and designed in various different configurations. Therefore, the detailed description of the embodiments of the present application with reference to the accompanying drawings is not intended to limit the protection scope of the present application, but merely to represent the selected embodiments of the present application. All other embodiments obtained by those of ordinary skill in the art based on the embodiments of the present application without creative efforts should fall within the protection scope of the present application.

In the description of the embodiments of the present application, it should be noted that the orientation or position relationship indicated by the terms, such as “upper”, “lower”, “left”, “right”, “vertical”, “horizontal”, “inside” and “outside”, is based on the orientation or position relationship shown in the accompanying drawings, or is the orientation or position relationship of usual placement the product of the present disclosure when in use, which is only for ease of description of the present application and the simplified description, rather than indicating or implying that the apparatuses or elements specified necessarily have a specific orientation or are constructed and operated in a specific orientation, and therefore cannot be construed as limiting the present application. In addition, the terms “first”, “second”, “third”, etc. are merely used for distinct description, and shall not be construed as indicating or implying relative importance.

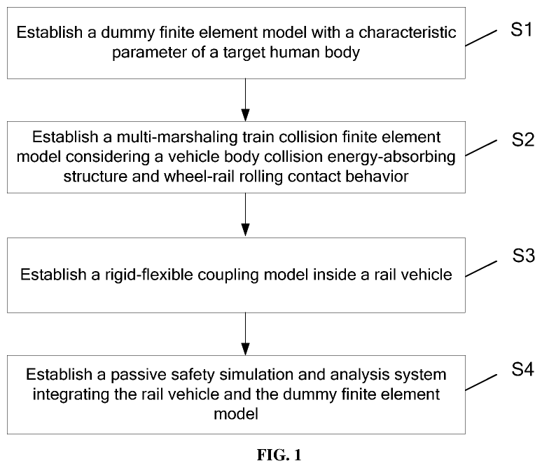

The present disclosure will be explained in detail below with reference to FIGS. 1 to 4.

### Embodiment 1

A modeling method for a rail vehicle collision finite element dummy and simulation system includes the following steps.

S1: Establish a dummy finite element model with a characteristic parameter of a target human body by calculating a scaling factor of the dummy finite element model in segments.

S2: Establish a multi-marshaling train collision finite element model considering a vehicle body collision energy-absorbing structure and wheel-rail rolling contact behavior.

S3: Establish a rigid-flexible coupling model inside a rail vehicle.

S4: Place the dummy finite element model obtained in step S1 into the multi-marshaling train collision finite element model obtained in step S2, and establish a passive safety simulation and analysis system integrating the rail vehicle and the dummy finite element model.

A principle of calculating a scaling factor of the dummy finite element model in segments is as follows: A Hypermorph module in Hypermesh, a piece of finite element preprocessing software, is used to scale different body segments of a European and American dummies finite element model; body segment division is performed on the European and American dummy finite element model, local coordinate systems are established, deformable bodies are established on outer surfaces of different body segments, a human body model is completely enveloped in the deformable bodies, and the deformable bodies are used to control a shape of the model to realize scaling of the model.

Selected target body segments are scaled by using the established local coordinate systems and deformable bodies and the calculated scaling factor in preparatory operations. When a body segment is scaled, other body segments connected thereto will also be deformed. Therefore, the sizes of the affected body segments need to be restored, and then other body segments are scaled. In this way, each body part of the human body model is scaled, and finally a dummy finite element model meeting the characteristic size of the target human body is obtained.

In step S1, the process of establishing a dummy finite element model with a characteristic parameter of a target human body by calculating a scaling factor of the dummy finite element model in segments includes:
first dividing a human body into a plurality of body segments, including a head, a neck, a trunk, an upper left arm, an upper right arm, a left forearm, a right forearm, a left thigh, a right thigh, a left shank, and a right shank, and then calculating a size scaling factor and a mass scaling factor for different body segments respectively, where λₓ, λ_{y} and λ_{z} are set as corresponding scaling factors of each body segment in X, Y and Z directions; in order to ensure that the scaled dummy finite element model and the dummy finite element model before the scaling have the same mass distribution, λₓ and λ_{y} are equal, and a relationship among λₓ, λ_{y} and λ_{z} is constrained by a mass scaling factor Rₘ;
the size scaling factor of the head is a ratio of sums of a head circumference, a head width and a head length, and is expressed as:

$${λ}_{x} = {λ}_{y} = {λ}_{z} = \frac{{( C + W + L )}_{S}}{{( C + W + L )}_{S}} , \qquad ( 1 )$$

where C represents the head circumference, W represents the head width, L represents the head length, and subscripts S and H represent the characteristic parameter of the target human body and a characteristic parameter of the European and American dummy finite element model respectively;
in order to ensure that the mass distribution of the scaled head is the same as that before the scaling, the mass scaling factor Rₘ is defined as the third power of the size scaling factor:

$$\frac{{M}_{S}}{{M}_{H}} = {R}_{m} = {λ}_{x}^{2} , \qquad ( 2 )$$

where the size scaling factor λ_{z} of the neck and trunk segments in the Z direction is determined by a vertical height of a human at a sitting posture, and is expressed as:

$${λ}_{z} = \frac{{( ESH )}_{S}}{{( ESH )}_{H}} , \qquad ( 3 )$$

where ESH is the vertical height at the sitting posture;
the mass scaling factor of the neck and trunk segments is determined according to a total weight of the human body, and is expressed as:

$${R}_{m} = \frac{{( TBW )}_{S}}{{( TBW )}_{H}} , \qquad ( 4 )$$

where TBW represents the weight of the human body;
in order to ensure that the mass distribution of the scaled dummy model is the same as that before the scaling, the size scaling factors λₓ and λ_{y} of the neck and trunk segments in the X and Y directions meet the following formula:

$${λ}_{x} = {λ}_{y} = \frac{\sqrt{{R}_{m}}}{\sqrt{{λ}_{z}}} , \qquad ( 5 )$$

and
a method for calculating the size scaling factors of the upper left arm, upper right arm, left forearm, right forearm, left thigh, right thigh, left shank and right shank segments is the same as a method for calculating the scaling factors of the neck and trunk segments, where the size scaling factor λ_{z} is a ratio of lengths of corresponding body segments of the target human body and the European and American dummy finite element model, and the mass scaling factor Rₘ is a ratio of mass of the corresponding body segments.

When the dummy finite element model with the characteristic parameter of the target human is established by calculating the scaling factor of the dummy finite element model in segments, the size and element mass of the scaled European and American dummy finite element model is checked to ensure that the element mass of the scaled model meets requirements; a deviation from a target size and mass is determined by comparing size and mass parameters of each body segment of the scaled model with size and mass parameters of the corresponding body segment of the target human body, and if an absolute value of the deviation is greater than 10%, scaling is performed again; when absolute values of size and mass deviations of all body segments are within the range of 10%, the size and mass of the scaled dummy finite element model meet requirements, the element mass of the model is further checked, and unqualified mesh elements are modified or re-divided, so as to obtain the dummy finite element model meeting requirements for the characteristic parameter of the target human body; and classical cadaver experimental data may be used to verify biological fidelity of the scaled dummy finite element model. The European and American dummy finite element model includes, but is not limited to, THUMS, GHBMC and WSU models.

In step S2, the process of establishing a multi-marshaling train collision finite element model considering a vehicle body collision energy-absorbing structure and wheel-rail rolling contact behavior includes:
determining a train marshaling form according to simulation requirements;
establishing finite element models of the energy-absorbing structure, a vehicle body, a bogie and a track of a train, extracting a mid-plane of a train solid model according to geometric structural characteristics of the train, and performing discretization by using a four-node shell element, where components of a mid-plane model and components of the solid model have the same connection mode, and a device on the train is simulated by using a mass element, and is connected to the vehicle body by using a three-node beam element;
establishing a wheel-rail rolling contact finite element model according to a wheel tread type and a track structure, discretizing the rail and a wheelset by using an eight-node solid element, simulating materials of wheels and the rail by using a *MAT_PIECEWISE_LINEAR_PLASTICITY elastic-plastic material model considering a strain rate effect, and setting automatic surface-to-surface contact between the wheel and the rail to locally refine a mesh of a wheel-rail contact area;
if the deformation of the wheel and the rail during a collision is not considered, using a *MAT_RIGID rigid material to simulate a wheel-rail material in order to reduce a calculation cost;
for a ballastless track structure, simulating a track slab and a mortar layer by using a *MAT_ELASTIC material model, simplifying a fastener system by using a spring-damping element, and simulating by using *MAT_SPRING_ELASTIC and *MAT_DAMPER_VISCOUS material models; and
applying the same translation speed to both the wheelset and the vehicle body, and applying a corresponding rotation speed to the wheel to simulate wheel-rail rolling contact behavior, so as to obtain the multi-marshaling train collision finite element model considering the vehicle body collision energy-absorbing structure and the wheel-rail rolling contact behavior.

In step S2, during the process of establishing a multi-marshaling train collision finite element model considering a vehicle body collision energy-absorbing structure and wheel-rail rolling contact behavior, according to mechanical properties of a coupler buffer apparatus, a discrete beam element is used to simulate the coupler buffer apparatus, and matches a *MAT_GENERAL_NONLINEAR_6DOF_DISCRETE_BEAM material model, travel failure is imposed on the beam element, and when the travel of the coupler buffer apparatus is greater than rated travel, the beam element automatically fails; and
according to geometric structural characteristics of the bogie, a bogie frame, a traction apparatus, an axle box and a related structure are discretized by a four-node shell element. A main body structure of the bogie is made of Q345. In order to reduce a calculation amount and shorten a calculation time, the deformation of the bogie is not considered during the collision, and thus the bogie is set as a rigid body. A discrete beam material model *MAT_LINEAR_ELASTIC_DISCRETE_BEAM is used to simulate an air spring and an axle box spring, and a traction seat is connected to a vehicle body bolster by using *CONSTRAINED_EXTRA_NODES_SET.

A process of establishing a dynamic constitutive relation related to a strain rate of a vehicle body material includes:
studying dynamic mechanical properties of a vehicle body structural material in a wide strain rate range by using an MTS universal testing machine, a high-speed material testing machine and a separated Hopkinson bar apparatus, establishing the dynamic constitutive relation related to the strain rate of the vehicle body material, and introducing the dynamic constitutive relation into the vehicle body finite element model.

In step S3, the process of establishing a rigid-flexible coupling model inside a rail vehicle includes:
during finite element modeling, simplifying a seat model, deleting parts irrelevant to seat motions and mechanical properties, and stiffening components that do not interact with drivers and passengers during a collision; discretizing a seat frame by using an eight-node solid element, and simulating a frame material; discretizing a backrest and a cushion of the seat by using an eight-node solid element, and simulating materials of the backrest and the cushion; discretizing a seat base by using an eight-node solid element, and simulating a base material; and connecting the seat finite element model to a train finite element model to obtain the rigid-flexible coupling model inside the rail vehicle.

Since the seat includes many different components, during finite element modeling, a model may be simplified, and parts irrelevant to seat motions and mechanical properties may be deleted, but it needs to be ensured that the simplified finite element model is consistent with the original model in mechanical properties. The seat frame is discretized by using an eight-node solid element, and a frame material is simulated by using *MAT_PIECEWISE_LINEAR_PLASTICITY.

The backrest and the cushion of the seat are usually made of polyurethane foam and fiber fabrics and are discretized by using an eight-node solid element, and the materials of the backrest and the cushion are simulated by using *MAT_LOW_DENSITY_FOAM.

The seat base is discretized by using an eight-node solid element, and a base material is simulated by using a *MAT_RIGID material model.

As a surface skin mainly provides a function of comfort and has a complex shape and its influence on passengers can be ignored, the skin may be deleted when the finite element model is established.

The seat finite element model is connected to a train finite element model by using *CONSTRAINED_EXTRA_NODES_SET.

In step S4, the process of establishing a passive safety simulation and analysis system integrating the rail vehicle and the dummy finite element model includes:
placing the dummy finite element model with the characteristic parameter of the target human body that is obtained in step S1 and the rigid-flexible coupling model inside the rail vehicle that is obtained in step S3 into the multi-marshaling train collision finite element model considering the vehicle body collision energy-absorbing structure and the wheel-rail rolling contact behavior and obtained in step S2; since a gap between the dummy model and the seat model cannot be completely eliminated in the preprocessing process, in order to consider the influence of an initial stress between the dummy and the seat and an initial stress between the train and a track system under a gravity field, performing contact static analysis on a dummy-seat model by using a dynamic relaxation function of LS-DYNA, to obtain a static displacement field/stress field;
performing contact static analysis by using an ANASYS implicit algorithm during initialization analysis; and
finally inputting the obtained static displacement field/stress field into the finite element model for stress initialization, and finally establishing the passive safety simulation and analysis system integrating the rail vehicle and the dummy finite element model that can predict damage of target drivers and passengers.

### Embodiment 2

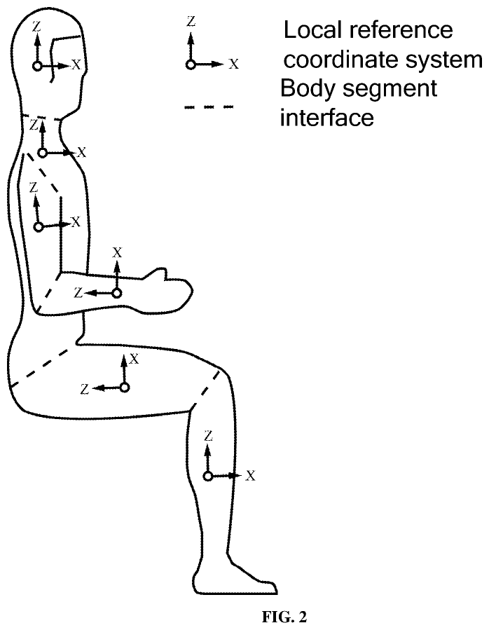

As shown in FIG. 2, the segmentation of human body segments and local reference coordinate systems are displayed. According to the segmentation, with reference to GB 10000-88 (Chinese adult body size) and GB/T17245-2004 (adult body inertia parameters), size and mass parameters of body segments of Chinese 50th percentile adult males are determined with Chinese 50th percentile adult male bodies as research objects.

It should be noted that in GB/T 17245-2004, the division of the head, the neck and the thigh is different from that in a segmentation scaling method. In GB/T 17245-2004, the head and the neck fall into one body segment, and the thigh also falls into one body segment. In the segmentation scaling method, the head and the neck fall into two parts, and the neck is included in a neck and trunk segment. In addition, the thigh is also divided into two parts, and a thigh segment only includes the thigh minus a flap part. Mass parameters of head segments and thigh segments of Chinese 50^{th} percentile adult males required for scaling cannot be directly obtained from GB/T 17245-2004, and the mass of the head segment and the thigh segment needs to be treated. Therefore, according to the proportion of the heads to the total weight of the heads and the necks of American human bodies and the proportion of the thigh minus the flap part to the whole thigh in NASA-STD-3000, the mass of the heads and the thigh segments of Chinese 50th percentile male bodies was calculated. Geometric sizes and mass of body segments of Chinese 50th percentile males and a THUMS-AM50 model are shown in Table 1 below:

TABLE 1
Sizes and mass of body segments of the Chinese
50^{th} percentile males and the THUMS-AM50 model

| Human | | Chinese 50^{th} | THUMS- |
|---|---|---|---|
| body | | percentile | AM50 |
| segment | Size/mass | males | model |
| Head | Mass (kg) of the head | 4.13 | 5.44 |
| | Head circumference (mm) | 560 | 618.01 |
| | Head width (mm) | 154 | 164.01 |
| | Head length (mm) | 184 | 210.71 |
| Neck and | Weight (kg) | 59 | 76.75 |
| trunk | Vertical height (mm) at a | 908 | 916 |
| | sitting posture | | |
| Upper arm | Mass (kg) of the upper arm | 1.46 | 2.89 |
| | Shoulder-elbow distance (mm) | 335 | 393.44 |
| Forearm | Mass (kg) of the forearm | 1.13 | 1.56 |
| | and the hand | | |
| | Elbow-fingertip distance (mm) | 42 | 476.93 |
| Thigh | Mass (kg) of the thigh | 5.24 | 6.71 |
| | Buttock-knee length (mm) | 554 | 625.39 |
| Shank | Mass (kg) of the shank and the | 3.09 | 4.85 |
| | foot | | |
| | Distance (mm) between the | 493 | 536.56 |
| | knee and the floor | | |

A scaling factor of each body segment of a dummy finite element model of Chinese 50th percentile males was calculated by using a segmentation scaling method, as shown in Table 2 below:

TABLE 2
Scaling factor of each body segment of a dummy finite
element model of Chinese 50th percentile males

| | Scaling factor | | | |
|---|---|---|---|---|
| Human body segment | Rₘ | λₓ | λ_{y} | λ_{z} |
| Head | 0.741 | 0.905 | 0.905 | 0.905 |
| Neck and trunk | 0.769 | 0.881 | 0.881 | 0.991 |
| Upper arm | 0.505 | 0.770 | 0.770 | 0.851 |
| Forearm | 0.724 | 0.907 | 0.907 | 0.881 |
| Thigh | 0.781 | 0.939 | 0.939 | 0.886 |
| Shank | 0.637 | 0.833 | 0.833 | 0.919 |

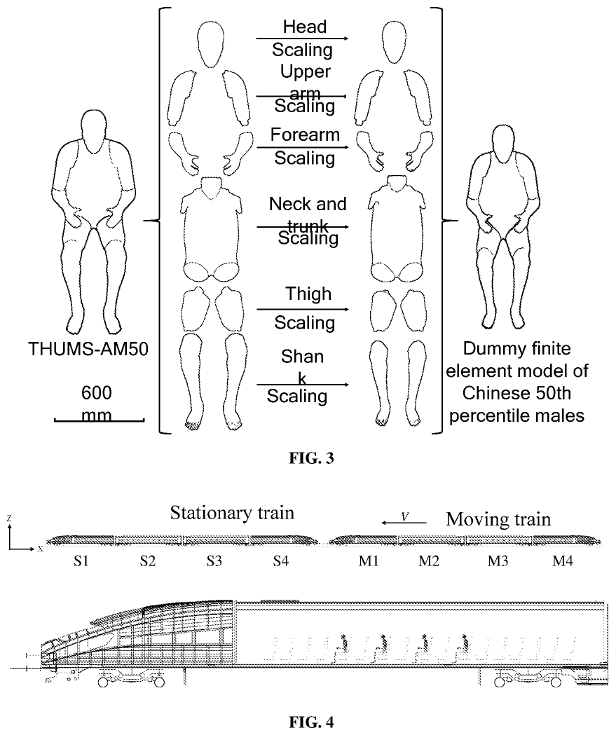

Then a Hypermorph module of a dummy finite element model THUMS-AM50 of European and American 50th percentile males in Hypermesh was scaled obtain a dummy finite element model of Chinese 50th percentile males, as shown in FIG. 3. The specific steps are as follows:

Body segment division is performed on a THUMS-AM50 dummy finite element model, local coordinate systems are established, deformable bodies are established on outer surfaces of different body segments, and a human body model is completely enveloped in the deformable bodies.

Selected target body segments are scaled by using the established local coordinate systems and deformable bodies and the calculated scaling factor in preparatory operations. Sizes of affected body segments are restored, and then other body segments are scaled. In this way, each body part of the human body model is scaled.

The size and element mass of the scaled model are checked to ensure that the size and element mass of the scaled model meet requirements. Then classical cadaver experimental data is used to verify biological fidelity of the scaled dummy model.

Finite element models of the energy-absorbing structure, a vehicle body, a bogie and a track of a train are established. A mid-plane of a vehicle body solid model is extracted according to geometric structural characteristics of the vehicle body, and discretization is performed by using a four-node shell element, where components of a mid-plane model and components of the solid model have the same connection mode, and a device on the train is simulated by using a mass element, and is connected to the vehicle body by using a three-node beam element. Considering that large deformation mainly occurs at the end of the vehicle when the train collides, in order to balance calculation accuracy and calculation efficiency, the mesh at the end of the vehicle body is refined to 30 mm, and a middle mesh is in transition at 80 mm.

Based on dynamic mechanical tests of vehicle body structural material in a wide strain rate range, an explicit or empirical dynamic constitutive relation related to the strain rate of the vehicle body material is established and introduced into the vehicle body finite element model. A discrete beam element is used to simulate the coupler buffer apparatus, and matches a *MAT_GENERAL_NONLINEAR_6DOF_DISCRETE_BEAM material model, travel failure is imposed on the beam element, and when the travel of the coupler buffer apparatus is greater than rated travel, the beam element automatically fails.

Structures such as a bogie frame, a traction apparatus and an axle box are discretized by a four-node shell element. A discrete beam material model *MAT_LINEAR_ELASTIC_DISCRETE_BEAM is used to simulate an air spring and an axle box spring, and a traction seat is connected to a vehicle body bolster by using *CONSTRAINED_EXTRA_NODES_SET.

A wheel-rail rolling contact finite element model is established according to a wheel tread type and a track structure, and discretizing is performed by using an eight-node solid element. The wheel tread type is S1002CN, with a radius of 430 mm, a rail profile is CN60, and a rail cant is 1:40. The track has a ballastless structure, and includes a rail, a fastener, a track slab and a mortar layer from top to bottom. Automatic surface-to-surface contact is set between the wheel and the rail to locally refine a mesh of a wheel-rail contact area; and the wheel and rail materials are simulated by using *MAT_RIGID. The same translation speed is applied to both the wheelset and the vehicle body, and a corresponding rotation speed is applied to the wheel to simulate wheel-rail rolling contact behavior.

According to the internal structure of existing rail vehicles in China, a rigid-flexible coupling model of rail vehicle seats is established.

During finite element modeling, a seat model is simplified, and parts irrelevant to seat motions and mechanical properties are deleted. The seat frame is discretized by using an eight-node solid element, and a frame material is simulated by using *MAT_PIECEWISE_LINEAR_PLASTICITY; a backrest and a cushion of the seat are discretized by using an eight-node solid element, and materials of the backrest and the cushion are simulated by using *MAT_LOW_DENSITY_FOAM. As skins on surfaces of the backrest and the cushion mainly provide a function of comfort and has a complex shape and its influence on passengers can be ignored, the skin is not modeled when the finite element model is established. The seat base is discretized by using an eight-node solid element, and a base material is simulated by using a *MAT_RIGID material model. The seat finite element model is connected to a train finite element model by using *CONSTRAINED_EXTRA_NODES_SET, to establish a passive safety simulation and analysis system integrating a rail vehicle and a dummy, as shown in FIG. 4.

A Chinese 50th percentile dummy finite element model is placed into a train collision finite element model, stress initialization is performed on a dummy-seat and train-track system under the gravity field by using an LS-DYNA dynamic relaxation command, and finally a train-dummy integrated simulation model and system for predicting damage of Chinese 50th percentile male drivers and passengers are established.

The above embodiments merely illustrate specific implementations of the present application, and the description thereof is more specific and detailed, but is not to be construed as a limitation to the protection scope of the present application. It should be noted that those of ordinary skill in the art can further make a plurality of modifications and improvements without departing from the concept of technical solutions of the present application. These modifications and improvements all fall within the protection scope of the present application.

1. A method for improving collision passive safety of rail vehicles, the method comprising the following steps:
S1: establishing a dummy finite element model with a characteristic parameter of a target human body by calculating a scaling factor of the dummy finite element model in segments; wherein a principle of calculating a scaling factor of the dummy finite element model in segments is as follows: body segment division is performed on a European and American dummy finite element model, local coordinate systems are established, deformable bodies are established on outer surfaces of different body segments, a human body model is completely enveloped in the deformable bodies, and the deformable bodies are used to control a shape of the model to realize scaling of the model; and S1 comprises: first dividing a human body into a plurality of body segments, comprising a head, a neck, a trunk, an upper left arm, an upper right arm, a left forearm, a right forearm, a left thigh, a right thigh, a left shank, and a right shank, and then calculating a size scaling factor and a mass scaling factor for different body segments respectively, wherein λₓ, λ_{y} and λ_{z} are set as corresponding scaling factors of each body segment in X, Y and Z directions; in order to ensure that the scaled dummy finite element model and the dummy finite element model before the scaling have the same mass distribution, λₓ and λ_{y} are equal, and a relationship among λₓ, λ_{y} and λ_{z} is constrained by a mass scaling factor Rₘ;
the size scaling factor of the head is a ratio of sums of a head circumference, a head width and a head length, and is expressed as:
$${λ}_{x} = {λ}_{y} = {λ}_{z} = \frac{{( C + W + L )}_{S}}{{( C + W + L )}_{S}} , \qquad ( 1 )$$
wherein C represents the head circumference, W represents the head width, L represents the head length, and subscripts S and H represent the characteristic parameter of the target human body and a characteristic parameter of the European and American dummy finite element model respectively;
in order to ensure that the mass distribution of the scaled head is the same as that before the scaling, the mass scaling factor Rₘ is defined as the third power of the size scaling factor:
$$\frac{{M}_{S}}{{M}_{H}} = {R}_{m} = {λ}_{x}^{2} , \qquad ( 2 )$$
wherein the size scaling factor λ_{z} of the neck and trunk segments in the Z direction is determined by a vertical height of a human at a sitting posture, and is expressed as:
$${λ}_{z} = \frac{{( ESH )}_{S}}{{( ESH )}_{H}} , \qquad ( 3 )$$
wherein ESH is the vertical height at the sitting posture;
the mass scaling factor of the neck and trunk segments is determined according to a total weight of the human body, and is expressed as:
$${R}_{m} = \frac{{( TBW )}_{S}}{{( TBW )}_{H}} , \qquad ( 4 )$$
wherein TBW represents the weight of the human body;
in order to ensure that the mass distribution of the scaled dummy model is the same as that before the scaling, the size scaling factors λₓ and λ_{y} of the neck and trunk segments in the X and Y directions meet the following formula:
$${λ}_{x} = {λ}_{y} = \frac{\sqrt{{R}_{m}}}{\sqrt{{λ}_{z}}} , \qquad ( 5 )$$
and
a method for calculating the size scaling factors of the upper left arm, upper right arm, left forearm, right forearm, left thigh, right thigh, left shank and right shank segments is the same as a method for calculating the scaling factors of the neck and trunk segments, wherein the size scaling factor λ_{z} is a ratio of lengths of corresponding body segments of the target human body and the European and American dummy finite element model, and the mass scaling factor Rₘ is a ratio of mass of the corresponding body segments;
S2: establishing a multi-marshaling train collision finite element model considering a vehicle body collision energy-absorbing structure and wheel-rail rolling contact behavior, comprising: establishing finite element models of the energy-absorbing structure, a vehicle body, a bogie and a track of a train, extracting a mid-plane of a train solid model according to geometric structural characteristics of the train, and performing discretization by using a four-node shell element, wherein components of a mid-plane model and components of the solid model have the same connection mode, and a device on the train is simulated by using a mass element, and is connected to the vehicle body by using a three-node beam element;
establishing a wheel-rail rolling contact finite element model according to a wheel tread type and a track structure, discretizing the rail and a wheelset by using an eight-node solid element, simulating materials of wheels and the rail by using an elastic-plastic material model considering a strain rate effect, and setting automatic surface-to-surface contact between the wheel and the rail to locally refine a mesh of a wheel-rail contact area; and
applying the same translation speed to both the wheelset and the vehicle body, and applying a corresponding rotation speed to the wheel, so as to obtain the multi-marshaling train collision finite element model considering the vehicle body collision energy-absorbing structure and the wheel-rail rolling contact behavior;
S3: establishing a rigid-flexible coupling model inside a rail vehicle, comprising during finite element modeling, simplifying a seat model, deleting parts irrelevant to seat motions and mechanical properties, and stiffening components that do not interact with drivers and passengers during a collision; discretizing a seat frame by using an eight-node solid element, and simulating a frame material; discretizing a backrest and a cushion of the seat by using an eight-node solid element, and simulating materials of the backrest and the cushion; discretizing a seat base by using an eight-node solid element, and simulating a base material; and connecting the seat finite element model to a train finite element model to obtain the rigid-flexible coupling model inside the rail vehicle;
S4: obtaining a damage response of the target drivers and passengers based on an integrated rail vehicle and dummy finite element model by placing the dummy finite element model with the characteristic parameter of the target human body that is obtained in step S1 and the rigid-flexible coupling model inside the rail vehicle that is obtained in step S3 into the multi-marshaling train collision finite element model considering the vehicle body collision energy-absorbing structure and the wheel-rail rolling contact behavior that is obtained in step S2, performing contact static analysis on a dummy-seat model by using a dynamic relaxation function of LS-DYNA, to obtain a static displacement field/stress field, and inputting the obtained static displacement field/stress field into the finite element model for stress initialization; and
S5: obtaining improved collision passive safety of the rail vehicles based on the damage response.

2. The method according to claim 1, wherein when a dummy finite element model with a characteristic parameter of a target human body is established by calculating the scaling factor of the dummy finite element model in segments, element mass of the scaled dummy finite element model is checked to ensure that the element mass of the scaled model meets requirements; a deviation from a target size and mass is determined by comparing size and mass parameters of each body segment of the scaled model with size and mass parameters of the corresponding body segment of the target human body, and if an absolute value of the deviation is greater than 10%, scaling is performed again; when absolute values of size and mass deviations of all body segments are within the range of 10%, the size and mass of the scaled dummy finite element model meet requirements, the element mass of the model is further checked, and unqualified mesh elements are modified or re-divided, so as to obtain the dummy finite element model meeting requirements for the characteristic parameter of the target human body.

3. The method according to claim 1, wherein the European and American dummy finite element model comprises THUMS, GHBMC and WSU models.

4. The method according to claim 1, wherein in step S2, during the process of establishing a multi-marshaling train collision finite element model considering a vehicle body collision energy-absorbing structure and wheel-rail rolling contact behavior, according to mechanical properties of a coupler buffer apparatus, a discrete beam element is used to simulate the coupler buffer apparatus, and matches a material model, travel failure is imposed on the beam element, and when the travel of the coupler buffer apparatus is greater than rated travel, the beam element automatically fails; and
according to geometric structural characteristics of the bogie, a bogie frame, a traction apparatus, an axle box and a related structure are discretized by a four-node shell element; a discrete beam material model is used to simulate an air spring and an axle box spring, and a traction seat is connected to a vehicle body bolster in a connection mode of using a rigid body and a deformable body.

5. The method according to claim 1, wherein a process of establishing a dynamic constitutive relation related to a strain rate of a vehicle body material comprises: studying dynamic mechanical properties of a vehicle body structural material in a wide strain rate range by using an MTS universal testing machine, a high-speed material testing machine and a separated Hopkinson bar apparatus, establishing the dynamic constitutive relation related to the strain rate of the vehicle body material, and introducing the dynamic constitutive relation into the vehicle body finite element model.

6. (canceled)
